(19) United States
(12) Patent Application Publication
(10) Pub. No.: US 2016/0027521 A1
(43) Pub. Date: Jan. 28, 2016

(54) METHOD OF FLASH CHANNEL CALIBRATION WITH MULTIPLE LUTS FOR ADAPTIVE MULTIPLE-READ

(71) Applicant: NXGN DATA, INC., Irvine, CA (US)

(72) Inventor: Guangming Lu, Irvine, CA (US)

(21) Appl. No.: 14/806,063

(22) Filed: Jul. 22, 2015

Related U.S. Application Data
(60) Provisional application No. 62/027,683, filed on Jul. 22, 2014.

(51) Int. Cl. G11C 16/26; G06F 11/10; G11C 29/52; G11C 11/56

(52) U.S. Cl. CPC G11C 16/26; G11C 11/56; G06F 11/1068; G11C 29/52

(57) ABSTRACT

Error Correction Codes, which are able to take soft-decision information, work much better when compared with hard-decision decoding. It can achieve much better performance. However, due to lack of direct soft-decision information for the NAND flash, multiple-reads with different voltage thresholds are used to generate the soft-decision information. Another invention disclosure describes a method to perform the multiple-read adaptively with different voltage threshold for the NAND flash in order to minimize the number of total multiple-read. The invention disclosure described here is a method of flash channel calibration, which will generate multiple LUTs for adaptive multiple-read with different voltage threshold.

### CROSS-REFERENCE TO RELATED APPLICATION(S)

The present application claims priority to and the benefit of U.S. Provisional Application No. 62/027,683, filed Jul. 22, 2014, entitled “METHOD OF FLASH CHANNEL CALIBRATION WITH MULTIPLE LUTS FOR ADAPTIVE MULTIPLE-READ”, the entire content of which is incorporated herein by reference.

### FIELD

One or more aspects of embodiments according to the present invention relate to a method of flash channel calibration with multiple LUTs for adaptive multiple-read.

### BACKGROUND

With the shrink of lithographic geometry for the NAND flash, the area of the memory cells get smaller, the number of electrons that can be used in storage drops, and it becomes more difficult to assure accurate information storage. Meanwhile high-capacity NAND flash memory can achieve high density storage by using multi-level cells (2 bits/cell for MLC or 3 bits/cell for TLC in the market) to store more than one bit per cell. Four and eight levels are currently in use, and the number of levels will increase further to provide more storage capability. The increasing number of levels (and smaller distance between levels) means that the lower signal-to-noise ratio of the read channel makes a stronger error-correction code (ECC) necessary. Reductions in feature size make inter-cell interference more likely.

All the above two factors increase the raw bit error rate (RBER), making powerful error correction coding necessary, e.g. low density parity check (LDPC) codes.

LDPC codes are linear block codes defined by sparse parity check matrices, called H-matrix. By optimizing the degree distribution, it is well-known that LDPC codes can approach the capacity of an AWGN channel. Designing LDPC codes with low error-floors is crucial for flash memory since storage systems usually require un-correctable bit-error-rates lower than 10⁻¹⁶ for enterprise class SSD. LDPC decoders commonly use soft reliability information about the received bits, which can greatly improve performance. However, typically flash systems have provided only hard decision information to their decoders. Traditional codes, such as BCH codes can only correct a specified, fixed number of errors. Unlike these traditional codes, it is difficult to guarantee a specified number of correctable errors for LDPC codes. However the average bit-error rate performance can often outperform that of BCH codes in Gaussian noise.

Since the sense amplifier comparator in the NAND flash only provides one bit of information about the threshold voltage, ECC decoders for NAND flash controller have historically relied on hard decision bits from the sense-amp comparator. However, soft information can be obtained either by reading from the same sense amplifier comparator multiple times with different word line voltages or by equipping flash cells with multiple sense amplifier comparators (or higher precision ADC) on the bit line. However, the NAND flash with multiple comparators is not currently available in the market.

FIG. 1 shows diagram 100 which shows an example for the behavior of multiple reads when two envelopes of “1” and “0” start to overlap. SLC is assumed in this example. V_{T} is the middle voltage while V_{T+} voltage is above V_{T} and V_{T-} is lower than V_{T}.

If a cell voltage is above reference voltage, it is considered as 0. Otherwise, it is considered as 1.

If multiple different reference voltages are applied, it will divide the whole voltage range into n+1 regions where n is the number of different reference voltages. In the above example, the 4 regions (region 3, 2, 1, 0) will be (−∞,V_{T-}), (V_{T-}, V_{T}), (V_{T}, V_{T+}), (V_{T+}, +∞) respectively.

If a cell with voltage in point A within region 3, it will be { 111 } with respect to voltage threshold {V_{T-}, V_{T}, V_{T+}} in this example.

If a cell with voltage in point B within region 2, it will be {011} with respect to voltage threshold {V_{T-}, V_{T}, V_{T+}} in this example.

If a cell with voltage in point C within region 1, it will be {001} with respect to voltage threshold {V_{T-}, V_{T}, V_{T+}} in this example.

If a cell with voltage in point D within region 0, it will be {000} with respect to voltage threshold {V_{T-}, V_{T}, V_{T+}} in this example.

By combining the outcomes of multiple-read, it is possible to generate the soft-decision information.

In the other hand, each T_{read} time is about 50 us for 2-bit/cell MLC, and above 100 us for 3-bit/cell TLC. The read of different threshold voltage of a certain flash page can only happen one at a time. Therefore it will save lots of time and power if we can make the multiple-read as less as possible. In other words, it will minimize the number of T_{read} and latency of M-RD. There is a need to enable this adaptive multiple-read for the NAND flash.

### SUMMARY

Aspects of embodiments of the present disclosure are directed toward a method of flash channel calibration with multiple LUTs for adaptive multiple-read.

### BRIEF DESCRIPTION OF THE DRAWINGS

These and other features and advantages of the present invention will be appreciated and understood with reference to the specification, claims and appended drawings wherein:

FIG. 1 is a an example for the behavior of multiple reads when two envelopes of “1” and “0” start to overlap;

FIG. 2 is a multi-LUT NAND flash channel calibration system, according to an embodiment of the present invention

FIG. 3 is a flow chart of detail calibration steps, according to an embodiment of the present invention

FIG. 4 is a diagram of flip count number as a function of voltage, according to an embodiment of the present invention

FIG. 5 is a diagram of an up-page of a multi-level cell (MLC), according to an embodiment of the present invention

FIG. 6 is a flow chart of a Log-Likelihood Ratio calculation, according to an embodiment of the present invention

### DETAILED DESCRIPTION

The detailed description set forth below in connection with the appended drawings is intended as a description of exemplary embodiments of a method of flash channel calibration with multiple LUTs for adaptive multiple-read provided in accordance with the present invention and is not intended to represent the only forms in which the present invention may be constructed or utilized. The description sets forth the features of the present invention in connection with the illustrated embodiments. It is to be understood, however, that the same or equivalent functions and structures may be accomplished by different embodiments that are also intended to be encompassed within the spirit and scope of the invention. As denoted elsewhere herein, like element numbers are intended to indicate like elements or features.

### Keywords

SoC—System on a Chip

SSD—Solid State Drive

SLC—Single-Level Cell

MLC—Multi-Level Cell

TLC—Thiple-Level Cell

ECC—Error Correction Codes

LDPC—Low Density Parity Codes

BER—Bit Error Rate

RBER—Raw Bit Error Rate

AWGN—Additive White Gaussian Noise

LUT—Look-Up-Table

M-RD—Multi-Read

CW—Code-Word

F/W—Firmware

LLR—Log-Likelihood Ratio

Embodiments of the invention are directed toward the method to obtain multiple sets of LUTs during NAND flash channel calibration for the adaptive multiple-read.

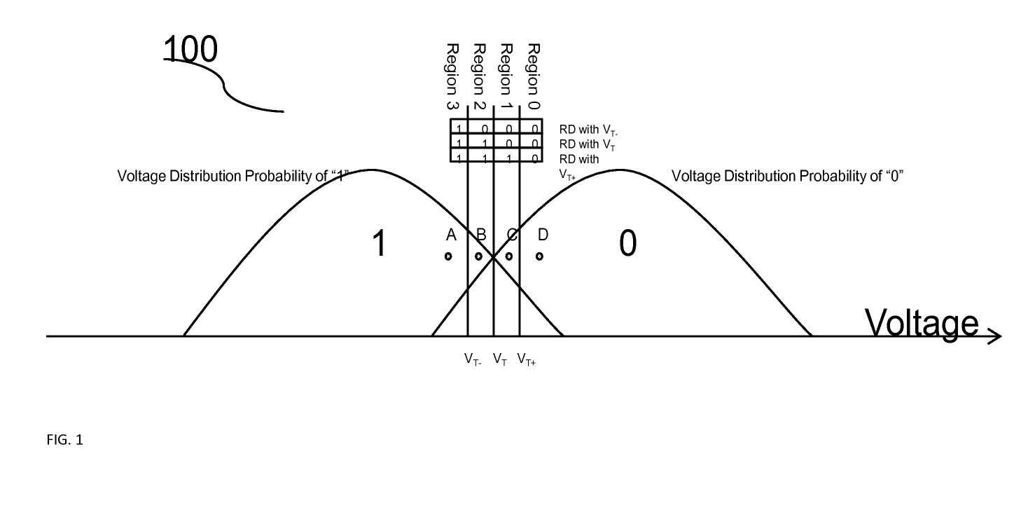

In order for ECC (or LDPC) decoder to perform adaptive multi-read scheme, it requires that the multiple sets of Look-Up-Tables (LUTs) are available. The LUTs are used to translate the pattern probability into soft-decision value. For example, as shown in the diagram 100 (FIG. 1), for the case of 3-read the LUTs for 3-read will translate the pattern {1 1 1} to soft-decision value S₃₀, {0 1 1} to S₃₁, {0 0 1} to S₃₂, {0 0 0} to S₃₃; for the case of 2-read the LUTs for 2-read will translate the pattern {1 1} to soft-decision value S₂₀, {0 1} to S₂₁, {0 0} to S₂₂; for the case of 4-read the LUTs for 4-read will translate the pattern {1 1 1 1} to soft-decision value S₄₀, {0 1 1 1} to S₄₁, {0 0 1 1} to S₄₂, {0 0 0 1} to S₄₃, {0 0 0 0} to S₄₄.

The LUT is used to translate the input bit pattern, for example {0 1 1}, into LLR soft-decision value for LDPC or other ECC method that is able to take soft-decision value. The LLR (Log Likelihood Ratio) is defined as

$$log ( \frac{P ( 0 )}{P ( 1 )} ) ,$$

where P(0) is the possibility of “0” to be the transmitted bit, while P(1) is the possibility “1” to be the transmitted bit.

The LLR calibration is to find the probability of pattern appearance in logarithmic domain. It is based on bit flip count of decoded data versus the raw data. In calibration mode, multiple LUTs corresponding to different number of M-RD will be generated. It is the necessary procedure in order to support the adaptive multi-read (M-RD). The LLR value generated in calibration phase will be the LUTs used to translate input pattern to LLR soft-decision input for ECC decoder in the normal multiple-read decoding phase.

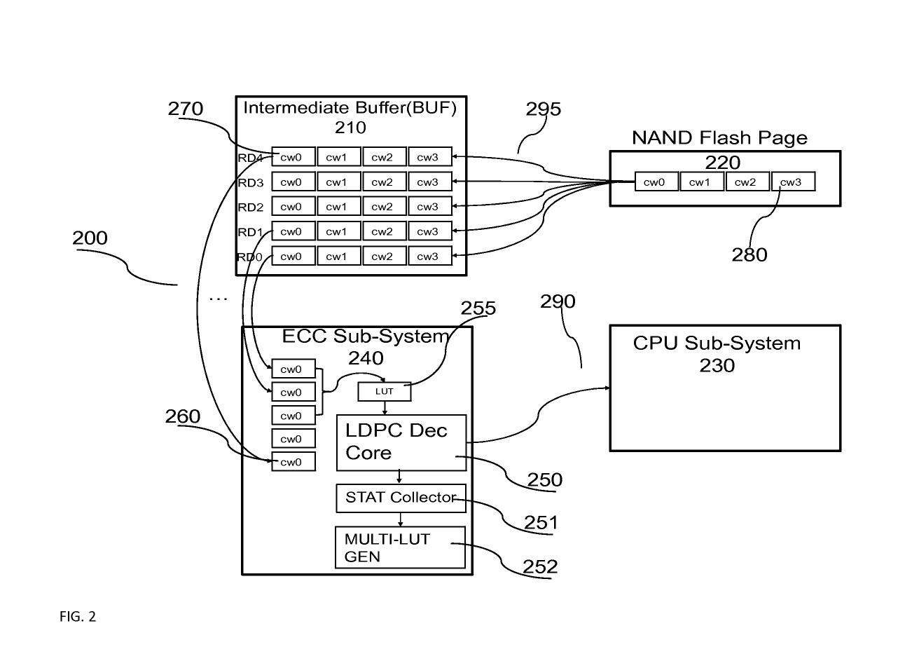

The multi-LUT NAND flash channel calibration system is presented in diagram 200 of FIG. 2. It is consisted of intermediate buffer 210, NAND flash memory array 220, CPU sub-system 230 and ECC sub-system 240.

The calibration starts to read out data from a NAND flash page 220 with a pre-defined maximum multiple-read to intermediate buffer 210. It can be configured to read out only one code-word 280 or the whole page (multiple code-words). When performing multiple-read, different voltage setting will be applied. Then the intermediate buffer 210 sends the same code-word from reads with different threshold voltage to ECC sub-system 240. Those code-words are stored in the local memory 260 inside ECC sub-system. The LDPC decoder 250 will use all copies or some copies of code-word in 260, combine them together using LUT 255 into soft-decision input to 250. The content in LUT 255 has the default or less-accurate contents. Once LDPC decoder 250 is able to decoder a code word successfully, the statistics collector 251 will collect the 1 to 0 or 0 to 1 flip count by comparing the decoded data with all of the raw data. The multi-LUT generation 252 will generate or update multiple LUTs based on current setting. The new generated LUTs in 252 has more accurate channel information than the contents in LUT 255 during NAND flash channel calibration phase. Hence it can reduce the LDPC decoding later on when using updated channel LUTs. CPU sub-system 230 can read out the content in 252 and store it for future use or populate to 255.

Calibration unit requires a correctly decoded code-word using either one copy or multi-copies of raw data. It will need all of the data corresponding to different read threshold to calibrate the LUT.

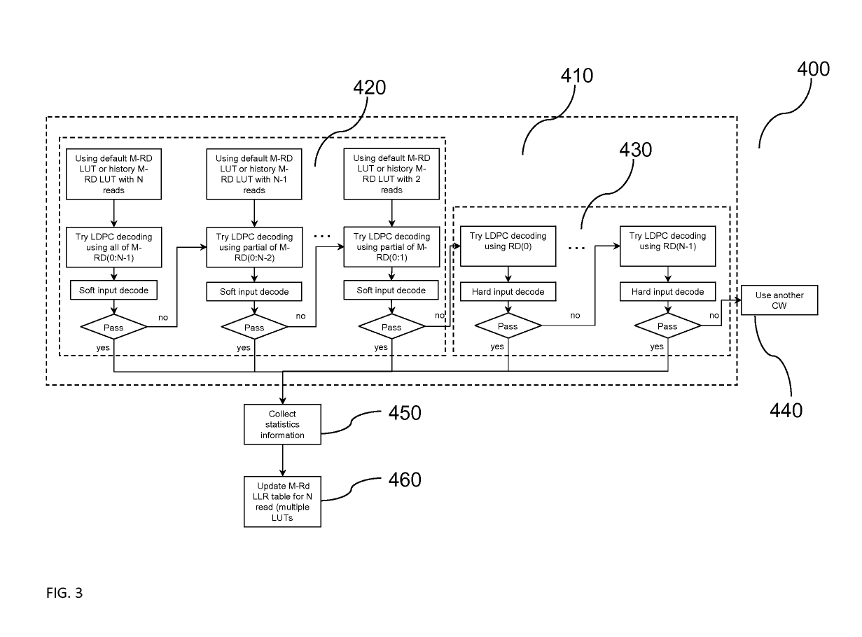

The detail calibration steps are shown diagram 400 of FIG. 3. It will try all copies of code-words with different threshold voltage first since it has the highest probability to be decodable. If not decodable, it will try some combinational copies of code-words next as shown in 420. If the combination of copies fails, the control will try to decode one copy of the codeword at a time as in 430. 410, which is the combination of 420 and 430, is to find a correctly decoded code-word by all different kinds of combination of raw code-word copies. If procedure 410 fails, firmware can choose another code-word in other NAND flash pages as in 440 to calibrate the NAND flash channel.

Once a code-word is decoded correctly by 410, statistics collector 251 or 450 will compare the correct code-word with each copy of the raw code-word and find out all of the bit flip count. It includes 0 to 1 count (z2o), which is the occurrences of 0 in decoded code-word and 1 in raw code-word in the same bit location; and 1 to 0 count (o2z), which is the occurrences of 1 in decoded code-word and 0 in raw code-word in the same bit location.

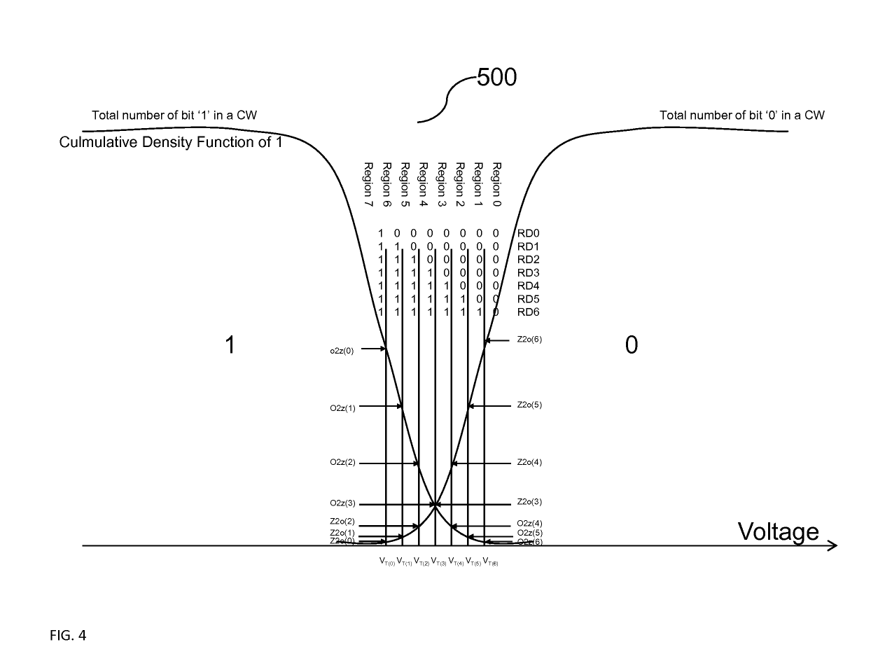

As shown in diagram 500 of FIG. 4, z2o(x) is the zero to one flip count number at voltage threshold V_{T(x)}; o2z(x) is the one to zero number at Voltage threshold V_{T(x)}. In 500, a 7-read calibration example is presented. Based on LLR definition, Pₓ(0) is proportional to the difference of neighboring z2o(x) at threshold V_{T(x)}; Pₓ(1) is proportional to the difference of neighboring o2z(x) at threshold V_{T(x)};.

Hence LLR(x)=C*log₂(delta(z2o(x))/delta(o2z(x)));

At the boundary of threshold, the total bit number of “0” or “1” should be used when calculating the difference. Meanwhile the LLR for different number of reads should have different boundary threshold.

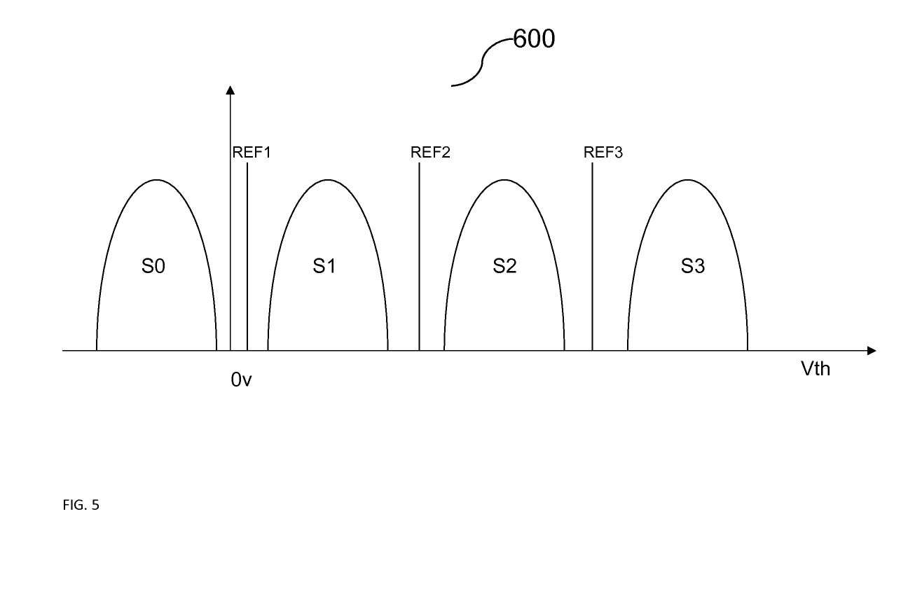

For the case of up-page read of MLC and TLC as well as middle page read of TLC, the o2z and z2o will represent the combined flip count at two or three internal voltage thresholds. For example, the o2z and z2o for up-page of MLC in 600 (see FIG. 5) will be the overall flip count at intersection REF1 and REF3. By providing the low-page and middle page (for TLC) information, it is also possible to differentiate the o2z and z2o in the intersection REF1 and REF3.

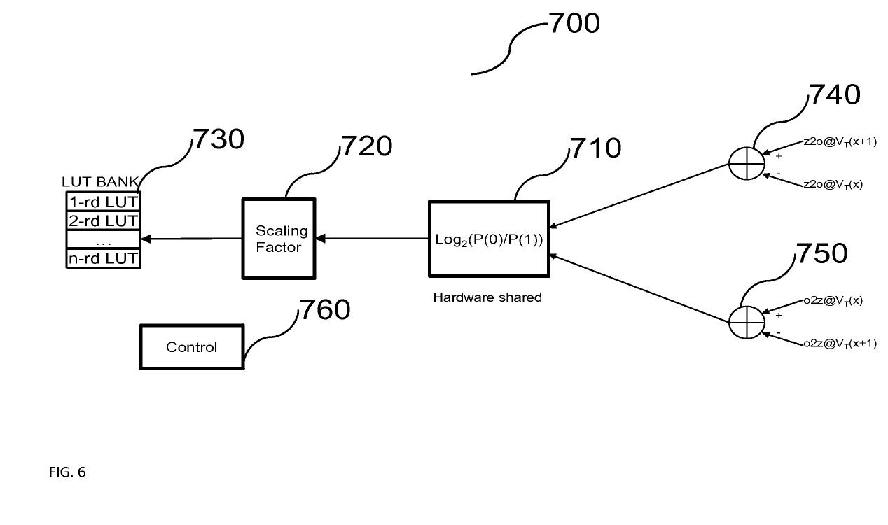

The last step of the calibration is to calculate the LLR value for each possible region with different voltage threshold. 700 (FIG. 6) shows the flow of LLR calculation. Step 740 and 750 are used to calculate the difference of flip count for zero to one and one to zero between 2 adjacent voltage thresholds. 710 will calculate the LLR. 720 will scale the LLR. Different sub-set of voltage thresholds can be selected to support adaptive multi-read. As in the diagram 500, by oscillating around the center voltage threshold V_{T(3)}, 1-read LLR, (one or more) 2-read LLR, 3-read LLR, . . . , 7-read LLR can be generated. The final multiple LLR (or LUT for multiple-read LLR translation in normal multiple-read) will be stored in the 730. Since NAND flash calibration is not time-critical procedure, the logarithmic logic 710 and difference logic 740 750 will be shared during the calculation of different LUTs. CPU sub-system 230 can collect the LUT in 730 for future usage or can populate the content in 730 to LUT 255 for more accurate LLR translation. Certainly, one has to pay attention that the voltage thresholds for normal multiple-read soft-decision decoding should be the same as voltage thresholds used for LUT calibration. By providing more accurate LLR translation, LDPC decoder may need less iterations to converge. Hence it can speed-up the throughput as well as reduce the power consumption and latency for multiple-read scenario.

### Advantages/Benefits of Embodiments of the Invention

With the multiple-LUT NAND flash channel calibration capability, it makes feasible to enable the adaptive multiple-RD. As such it can minimize the number of multiple reads once the M-RD is required. Hence it can reduce SSD latency once the M-RD happens.

Feasibility/Proof of Concept/Results Demonstration

An embodiment of the invention is the enabler for the adaptive multiple-read decoding, which has been proven to be effective to reduce the M-RD latency in case M-RD is needed. It is much more effective than the RAID recovery approach in case single read is not able to decode a code-word.

### Discoverability

The adaptive multiple-read feature can be observed via monitoring the flash channel data traffic. If the same NAND flash page is read out after the threshold voltage adjustment by variable number times within a program and erase interval, then most likely adaptive multiple-read feature is implemented. Once adaptive multiple-read feature is identified, similar approach as embodiments of the present invention disclosure will be there either in hardware or firmware/software.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section, without departing from the spirit and scope of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that such spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the inventive concept. As used herein, the terms “substantially,” “about,” and similar terms are used as terms of approximation and not as terms of degree, and are intended to account for the inherent deviations in measured or calculated values that would be recognized by those of ordinary skill in the art. As used herein, the term “major component” means a component constituting at least half, by weight, of a composition, and the term “major portion”, when applied to a plurality of items, means at least half of the items.

As used herein, the singular forms “a”, “an” and “the” are intended to include the plural forms as well, unless the context clearly indicates otherwise. It will be further understood that the terms “comprises” and/or “comprising”, when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list. Further, the use of “may” when describing embodiments of the inventive concept refers to “one or more embodiments of the present invention”. Also, the term “exemplary” is intended to refer to an example or illustration. As used herein, the terms “use,” “using,” and “used” may be considered synonymous with the terms “utilize,” “utilizing,” and “utilized,” respectively.

It will be understood that when an element or layer is referred to as being “on”, “connected to”, “coupled to”, or “adjacent to” another element or layer, it may be directly on, connected to, coupled to, or adjacent to the other element or layer, or one or more intervening elements or layers may be present. In contrast, when an element or layer is referred to as being “directly on”, “directly connected to”, “directly coupled to”, or “immediately adjacent to” another element or layer, there are no intervening elements or layers present.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein.

Although exemplary embodiments of a method of flash channel calibration with multiple LUTs for adaptive multiple-read have been specifically described and illustrated herein, many modifications and variations will be apparent to those skilled in the art. Accordingly, it is to be understood that a Disclosure—Method of Flash Channel Calibration with Multiple LUTs for Adaptive Multiple-Read constructed according to principles of this invention may be embodied other than as specifically described herein. The invention is also defined in the following claims, and equivalents thereof.

What is claimed is:

1. An SSD storage device that enables the multiple read for a same flash page by setting different threshold voltage.

2. The SSD system of claim 1 that issues a pre-defined maximum number of multi-read commands to flash memory.

3. The SSD system of claim 2 that consists of soft-decision and hard-decision ECC decoder, statistics information collector and NAND flash calibration control logic capable for multiple-LUT generation.

4. The SSD system of claim 3 that tries to decode a code-word successfully using either soft-decoding or hard-decoding approach by one or more copies of raw code-words corresponding to different voltage threshold.

5. The SSD system of claim 4 that count the flip number from zero to one and one to zero by comparing the decoded code-words with all copies of raw un-decoded code-words.

6. The SSD system of claim 5 that is able to differentiate flip count from zero to one and one to zero at different intersection by providing low-page and/or middle page.

7. The SSD system of claim 5 that uses one to zero and zero to one flip count to calculate the multiple-read LLR LUT.

8. The SSD system of claim 7 that can choose any combination of voltage thresholds within the total maximum thresholds.

9. The SSD system of claim 8 that can generate multiple-LUTs (one LUT for each voltage threshold combination) for less or equal number of M-RD in one calibration process.

10. The SSD system of claim 6 that uses the generated multiple-LUTs to support adaptive multiple-read or non-adaptive multiple-read during normal multiple-read decoding process.
